(19) United States
(12) Patent Application Publication
(10) Pub. No.: US 2003/0034857 A1
(43) Pub. Date: Feb. 20, 2003

(54) Multiplexer using ceramic filter as stacked satellite down converter

(75) Inventor: Mao-Jen Chen, Chung-li City (TW)

Correspondence Address: DOUGHERTY & TROXELL, Suite 1404, 5205 Leesburg Pike, Falls Church, VA, 22041, US

(73) Assignee: Prime Electronics & Statellitcs Inc.

(21) Appl. No.: 09/928,418

(22) Filed: Aug. 14, 2001

(51) Int. Cl. H03H 7/46

(52) U.S. Cl. 333/132

(57) ABSTRACT

A multiplexer using a ceramic filter as stacked satellite down converter is operative to reduce useless wave ranges in a wave frequency and to largely reduce external interferences with frequency ranges. The multiplexer is implemented by serially connecting a low-noise amplifier, a mixer, and an IF amplifier between a receiver and an output port of a satellite down converter, and the multiplexer is characterized in that a ceramic filter is serially connected between the IF amplifier and themixer. The ceramic filter has characteristics that enable reduction of useless wave ranges in a wave frequency and largely reduced external interference with frequency ranges.

### FIELD OF THE INVENTION

The present invention relates to a multiplexer using a ceramic filter as stacked satellite down converter, and more particularly to a multiplexer using a ceramic filter as stacked satellite down converter that has a ceramic filter serially connected between an intermediate frequency (IF) amplifier and a self-oscillating down converter and is therefore able to reduce useless wave ranges in a wave frequency and to reduce external interference with frequency ranges.

### BACKGROUND OF THE INVENTION

With the quick and prosperous development in the communication industry, there are more and more occasions in which a satellite is utilized to transmit signals. To receive and process signals transmitted through the satellite, it is necessary to set up receiving horn antenna and satellite down converter on the ground.

In the case of a conventional satellite down converter as shown in FIG. 1, a low-noise amplifier 11, an intermediate frequency (IF) amplifier 12, a mixer 13, a local oscillator 14, and a low-pass filter (LPF) 15 are serially connected between a receiver 10 and an output port 16, and a low-noise amplifier 11′, an intermediate frequency (IF) amplifier 12′, a mixer 13′, a local oscillator 14′, and a high-pass filter (HPF) 15′ are serially connected between a receiver 10′ and the same output port 16. With the above-described circuit structure, signals transmitted through the satellite are processed and output to an apparatus.

The above-mentioned low-pass filter 15 and the high-pass filter 15′ that are known in the art typically include a circuit composed of inductance and capacitance. Due to inherent characteristics of the inductance and capacitance, such type of circuit produces a large error. Please refer to FIG. 2. The solid line 18 indicates a stable wave frequency having obviously separated waves. However, due to the inherent characteristics of the inductance and capacitance, the wave frequency drifts with changes in temperature to finally become a state as indicated by the broken line 19 of FIG. 2. Waves as indicated by the broken line 19 have overlapped cut-off frequency that would seriously adversely affect the signal receiving ability of the satellite down converter. Moreover, such wave frequency is subjected to external interference with frequency ranges.

In view of the drawbacks existing in the conventional satellite down converter, it is tried by the inventor to develop a multiplexer operative to make the signal output from the local oscillator more stable and not easily subjected to external interference with frequency ranges.

### SUMMARY OF THE INVENTION

It is a primary object of the present invention to provide a multiplexer that uses a ceramic filter as a stacked satellite down converter operative to make the signal output from the local oscillator more stable and not easily subjected to external interference with frequency ranges.

To achieve the above and other objects, the multiplexer of the present invention is implemented by serially connecting a low-noise amplifier, a mixer, a local oscillator, and an IF amplifier between a receiver and an output port of a satellite down converter, and the multiplexer is characterized in that a ceramic filter is serially connected between the IF amplifier and the mixer.

The ceramic filter has characteristics that enable reduction of useless wave ranges in a wave frequency and largely reduced external interference with frequency ranges.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic circuit diagram of a conventional satellite down converter;

FIG. 2 is a graph showing waveforms processed by the conventional satellite down converter of FIG. 1; and

FIG. 3 is a schematic circuit diagram of a multiplexer according to the present invention.

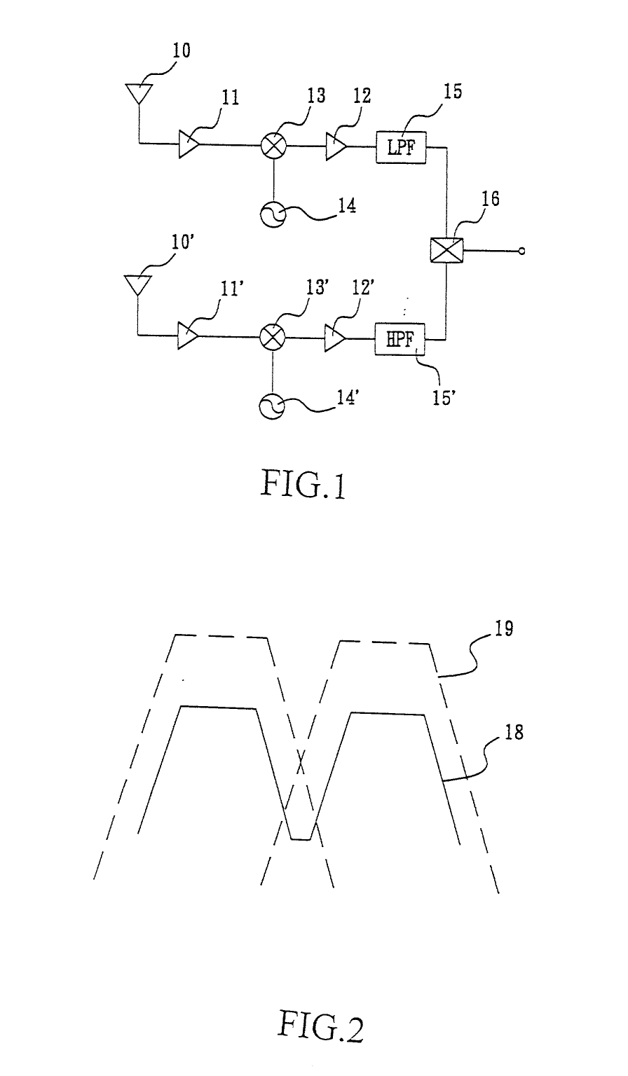

### DETAILED DESCRIPTION OF THE PREFERRED EMBODIMENTS

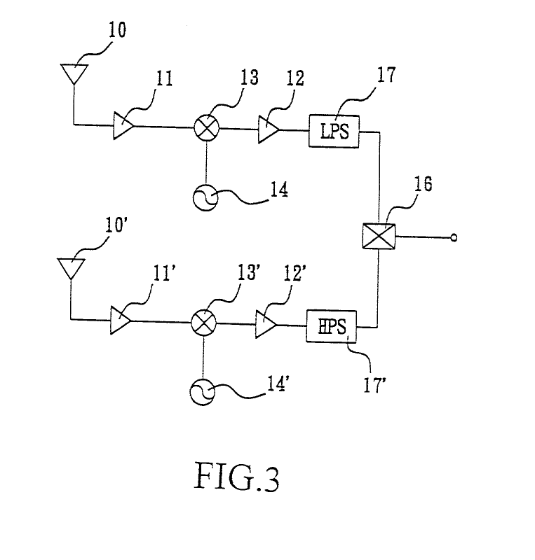

Please refer to FIG. 3 that is a schematic circuit diagram of a multiplexer according to the present invention. As shown, the multiplexer includes two receivers 10 and 10′ and an output port 16. A low-noise amplifier 11, an intermediate frequency (IF) amplifier 12, a mixer 13, a field effect transistor (MESFET) 14 serving as a local oscillator, and a low-pass ceramic filter (LPS) 17 are serially connected between the receiver 10 and the output port 16; and a low-noise amplifier 11′, an IF amplifier 12′, a mixer 13′, a field effect transistor (MESFET) 14′ serving as a local oscillator, and a high-pass ceramic filter (HPS) 17′ are serially connected between the receiver 10′ and the same output port 16. Since the ceramic filters 17, 17′ have characteristics that do not easily change with temperature and are therefore more stable than the conventional filters 15, 15′ composed of inductance and capacitance. The problem of overlapped cut-off frequencies is therefore eliminated in the case of ceramic filters 17, 17′. Moreover, due to the stable characteristics, the ceramic filters 17, 17′ are not easily subjected to external interference with frequency ranges.

Since it is easy for a person having ordinary skill in the art to implement and modify the circuits of filters composed of inductance and capacitance and of ceramic filters of the present invention based on the disclosure of the present invention, the arrangement for the circuits of the ceramic filters of the present invention is not discussed in details herein. However, it should be noted that the use of a ceramic filter necessitates changes of associated pins and the present invention is therefore not simply a replacement of some electronic elements.

In conclusion, due to the inherently unstable characteristics of the inductance and capacitance, the conventional high-pass and low-pass filters composed of inductance and capacitance tend to cause frequencies drifting when there are changes in temperature, and such frequencies are easily subjected to external interference with frequency ranges. In the present invention, ceramic filters are used to replace the conventional filters in the circuit of the conventional satellite down converter to solve the above-mentioned problem and largely upgrade the quality of received and processed signals.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A multiplexer using a ceramic filter as stacked satellite down converter, comprising receivers and an output port, and a low-noise amplifier, a mixer, a local oscillator, and an IF amplifier serially connected between each said receiver and said output port, and said multiplexer being characterized in that a ceramic filter is serially connected between each said IF amplifier and each said mixer.
